(19) United States
(12) Patent Application Publication
(10) Pub. No.: US 2022/0006453 A1
(43) Pub. Date: Jan. 6, 2022

(54) SWITCHING DEVICE, VOLTAGE SUPPLY SYSTEM, METHOD FOR OPERATING A SWITCHING DEVICE AND PRODUCTION METHOD

(71) Applicant: Lisa Draexlmaier GmbH, Vilsbiburg (DE)

(72) Inventors: Alexander IMMEL, Ergolding (DE); Stefan Johann HOFINGER, Sankt Wolfgang (DE)

(73) Assignee: Lisa Draexlmaier GmbH, Vilsbiburg (DE)

(21) Appl. No.: 17/479,738

(22) Filed: Sep. 20, 2021

Related U.S. Application Data
(63) Continuation of application No. PCT/EP2020/057678, filed on Mar. 19, 2020.

(30) Foreign Application Priority Data
Mar. 20, 2019 (DE) 10 2019 107 112.7

(51) Int. Cl. H03K 17/567; B60L 3/00; H03K 17/0814; H03K 17/16; H03K 17/10

(52) U.S. Cl. CPC H03K 17/567; B60L 3/0023; H03K 17/10; H03K 17/162; H03K 17/08148

(57) ABSTRACT

A switching device for a supply line for supplying electrical loads with electricity includes a power input, a power output, a controlled switching element, and a regulated resistance. The controlled switching element is disposed electrically between the power input and the power output and is configured to electrically couple the power input to the power output in a controlled manner. The regulated resistance is disposed electrically parallel to the controlled switching element. The regulated resistance is configured to electrically connect the power input to the power output during opening of the controlled switching element and occurring of voltage spikes between the power input and the power output. A voltage supply system, a method, and a manufacturing method are provided.

### CROSS-REFERENCE TO RELATED APPLICATIONS

This application is a continuation of International Application No. PCT/EP2020/057678, filed on Mar. 19, 2020, which claims priority to and the benefit of DE 10 2019 107 112.7, filed on Mar. 20, 2019. The disclosures of the above applications are incorporated herein by reference.

### FIELD

The present disclosure relates to a switching device for a supply line for supplying electrical loads with electricity. Furthermore, the present disclosure relates to a corresponding voltage supply system, a corresponding method for operating a switching device, and a corresponding manufacturing method.

### BACKGROUND

The statements in this section merely provide background information related to the present disclosure and may not constitute prior art.

In modern vehicles, it is attempted to reduce fuel consumption and thus the emission of harmful gases. One possibility therefor consists of supporting the internal combustion engine in the vehicle by an electric motor or replacing the internal combustion engine by an electric motor.

In such vehicles, stable supply networks consequently must be installed for high-power electric motors. In such supply networks, e.g., nominal voltages of several hundred volts can be provided, and the electric motors can have powers of several hundred kilowatts.

In particular, in cases of electrical issues, when, for example, a short circuit is detected in the supply network, the voltage supply must be quickly and reliably interrupted. However, since each supply line in the electrical system has ohmic-inductive properties, an abrupt switching-off of the supply voltage can lead to high voltage spikes in the supply network.

### SUMMARY

This section provides a general summary of the disclosure and is not a comprehensive disclosure of its full scope or all of its features.

The present disclosure is described in the following primarily in connection with electric vehicles. However, it is understood that the present disclosure can be used in any application wherein electrical loads should be reliably switched off.

The present disclosure makes possible a secure switching-off of inductive loads using the constructively simple means.

In one form, a switching device for a supply line for supplying electrical loads with electrical energy includes a power input, a power output, a controlled switching element, which is electrically disposed between the power input and the power output, and which is configured to electrically couple the power input to the power output in a controlled manner, and a regulated resistance, which is disposed electrically parallel to the controlled switching element, and which is configured to electrically connect the power input to the power output during opening of the controlled switching element and occurring of voltage spikes between the power input and the power output.

A voltage supply system for supplying electrical loads with electrical energy includes an electrical energy source and a switching device, wherein the power input of the switching device is coupled to a positive power output of the energy source, and wherein the power output of the switching device is couplable to a positive load connection of the electrical loads.

A method for operating a switching device for a supply line for supplying electrical loads with electrical energy includes the steps of controlling a controlled switching element in the switching device, which is disposed electrically between a power input and a power output of the switching device, and which is configured to electrically couple the power input to the power output in a controlled manner or to separate them from each other, and connecting of the power input and the power output using an electrical connection via a regulated resistance, which is disposed electrically parallel to the controlled switching element, during opening of the controlled switching element and occurring of voltage peaks.

A manufacturing method for a switching device for switching in a supply line for supplying electrical loads with electrical energy includes the steps of disposing of a controlled switching element electrically between a power input and a power output of the switching device, which is configured to electrically couple the power input to the power output in a controlled manner, and disposing of a regulated resistance electrically parallel to the controlled switching element, which is configured to electrically connect the power input to the power output during opening of the controlled switching element and occurring of voltage spikes between the power input and the power output.

The present disclosure is based on the recognition that in particular in applications with inductive loads, high voltage spikes can occur during switching-off of the loads.

For use with several hundred volts, as is common in electric vehicles, only very expensive switching elements are known that make possible a safe switching-off of inductive loads. So-called RCD snubbers require a large installation space and are very cost-intensive. The use of flyback diodes requires access to the negative power path, which is usually not possible in power distributors or electronic safety mechanisms, since here no negative lines are carried along.

However, the present disclosure provides a simple possibility of removing voltage spikes arising during switching-off of a load. For this purpose, the present disclosure provides the switching device, which can be disposed in a voltage supply system, for example, in the positive power path between the energy source and the load.

The switching device includes a power input and a power output, between which a controlled switching element and a regulated resistance are disposed. Here the controlled switching element and the regulated resistance are disposed electrically parallel to each other.

Here the controlled switching element serves for switching the electrical power. It can thus be closed and opened in a controlled manner. As explained above, in particular during separating or opening of the circuit with inductive loads, high voltage spikes can occur. Under certain circumstances these can damage the controlled switching element.

For this reason, in addition to the switching element the regulated resistance is provided. The regulated resistance is embodied here such that in normal operation, i.e., in the static state of the controllable switching element, it is high-resistance, i.e., there is no electrical connection between the power input of the switching device and the power output of the switching device. With statically opened or closed controllable switching element, the electrical connection between the power input of the switching device and the power output of the switching device is consequently interrupted via the regulated resistance; no or only a negligible current flows via the regulated resistance.

However, if the controlled switching element is opened, and voltage spikes occur here between power input and power output of the switching device, the regulated resistance connects the power input of the switching device and the power output of the switching device to each other electrically. The controllable resistance thus reduces its resistance, so that a current can flow between the power input of the switching device and the power output of the switching device.

Consequently, inductively stored energy is removed via the regulated resistance, i.e., at least partially converted into thermal energy. The regulated resistance provides an electrical connection between the power input of the switching device and the power output of the switching device when a voltage spike must be removed. After the voltage spike is removed, the regulated resistance is high-resistance. A new voltage spike can consequently form, and the controlled resistance can again become low-resistance. This process can be repeated multiple times until the stored energy has been completely removed.

Due to the separating of the switching function—controlled switching element—and the protective function—regulated resistance—the present disclosure provides a very simple possibility of switching off inductive loads.

Further forms and refinements arise from the dependent claims, as well as from the description with reference to the Figures.

In one form the controlled switching element can include a semiconductor switch, in particular a MOSFET, or a parallel circuit of at least two semiconductor switches, in particular MOSFETs.

MOSFETs are semiconductor components that are available in the most diverse variants. MOSFETs are well suited in particular for switching tasks, since they can be switched without power and make possible very fast switching processes. Depending on the maximum power or maximum current via the switching device, a single MOSFET or a parallel circuit made of MOSFETs can be provided here.

A MOSFET can in principle also be used as a regulated resistance. This operating mode is also called, for example, linear operation or linear mode. However, on the part of the semiconductor manufacturer, the linear mode is always recommended only for a single component. This limitation is due to the spread of the component parameters, above all the spread of the gate threshold voltage V_{GS(th)}. This means that with a parallel circuit of MOSFETs, the MOSFET having the lowest gate threshold voltage V_{GS(th)} is relocated as the first in the linear mode, and most losses are removed by it. The MOSFET technology ensures the further use limitations of the linear mode with MOSFETS connected in parallel. Many individual cells are connected in parallel in a package, and the gate threshold voltage V_{GS(th)} has a positive temperature coefficient. The cells can thereby drift further apart thermally, and the MOSFET having the lowest gate threshold voltage V_{GS(th)} is destroyed.

However, in the switching device, in particular in high-power applications such as electric vehicles, a plurality of MOSFETs can be connected in parallel. The drain-source on-state resistance, also R_{DS(on)}, is thereby kept low, and losses are minimized. However, the semiconductor switch as an efficient circuit switch consequently cannot be used for energy removal via the power-MOSFETs.

In a further form the regulated resistance can include a semiconductor switching element. A power input of the semiconductor switch element can be coupled to the power input of the switching device, and a power output of the semiconductor switch element can be coupled to the power output of the switching device.

Semiconductor switching elements other than MOSFETs can advantageously be used as regulated resistances. Such semiconductor switch elements can have disadvantages that can make them appear less suitable as a switch. For example, the switching speed of such semiconductor switch elements can be lower, and their drain-source on-state resistance can be higher than with MOSFETs. However, such semiconductor switching elements, such as, for example, IGBTs, can have a very high current capacity and dielectric strength.

In another form, the switching device can include a control input, wherein a switching input of the controlled switching element can be coupled to the control input via a first series resistor, and/or wherein a control input of the regulated resistance can be coupled to the control input via a second series resistor.

Due to the connecting of the control input of the controlled switching element and of the control input of the regulated resistance, it is ensured that the controlled switching element and the regulated resistance are always synchronously controlled, and their control inputs lie at defined signal levels.

In one form, the regulated resistance can be configured as an insulated-gate bipolar transistor (“IGBT”). A Zener diode can be disposed in the blocking direction between the power input of the switching device and a control input of the IGBT.

As already indicated above, an IGBT can be used as a regulated resistance. Such a system combines the advantages of the bipolar transistor, namely a good transmittance, a high blocking voltage, and robustness, and the advantages of a field-effect transistor, namely the nearly powerless controlling. IGBTs have a bipolar construction. This makes possible significantly higher current densities and thus also higher pulse energies. In terms of technology, IGBTs are therefore significantly better for the linear mode than MOSFETs. A single IGBT can consequently already be sufficient to protect a switching element including a parallel circuit of a plurality of MOSFETs.

During switching-off of the load, i.e., during opening of the controlled switching element, the voltage increases between the power input and the power output of the switching device until the Zener diode is conductive. If the Zener diode is conductive, a voltage is applied to the control input of the IGBT, and the resistance of the power path of the IGBT decreases. The load stream commutates from the controlled switching element to the IGBT. The energy stored in the system by induction ensures that the Zener diode is located on the boundary or in the transition between the conducting and blocked state. Thus, the IGBT also remains in a regulated state. In this state, the IGBT represents a voltage-controlled resistance, on which load connections (collector-emitter path), a nearly constant voltage, the Zener or Z voltage or breakdown voltage of the Zener diode plus gate source voltage, V_{GS(th)}, is applied and via which the current flows. As explained above, this operating type of a power semiconductor is referred to as linear mode or linear operation.

The IGBT remains in the conducting state until the Z voltage of the Zener diode is fallen below. The IGBT thereby loses its control and returns to the blocked state again. The energy stored in the system then leads to a renewed voltage increase between the power input and the power output of the switching device until the Zener diode and the IGBT are conductive again. This process lasts until the stored energy is removed. Here the IGBT is in a controlled state. Due to the gate-source voltage, its conductivity is regulated such that the product of the load current, which decreases nearly linearly, and its gate-source on-state resistance remains nearly constant.

In another form, the Zener diode can be dimensioned such that its breakdown voltage lies above a maximum voltage permitted for the controlled switching element.

If the electrical load switches, for example, with very high instantaneous currents in the case of a short circuit, then due to the energy stored in the system by induction, a steep voltage increase arises between the power input and the power output of the switching device. However, the maximum dielectric strength of the power MOSFETs must not be exceeded here. For this reason, the Zener diode can be chosen such that the value of the drain-source on-state voltage remains below the permitted limit or below the permitted maximum voltage.

In a further form, the switching device can include a damping element, in particular a series circuit made of a capacitance and a resistance, which is disposed between the power input of the switching device and the power output of the switching device.

The damping element is consequently disposed electrically parallel to the controlled switching element and the regulated resistance. During opening of the controlled switching element, the current commutates from the controlled switching element to the regulated resistance. Due to the, albeit small, inductances in the supply line to the regulated resistance and its input capacitance, this current commutation process can last a certain amount of time, typically under 100 ns. During this time, in order to inhibit an unreliable voltage increase on the controlled switching element, and thus a destruction thereof, the damping element can be provided parallel to the controlled switching element.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 shows a block circuit diagram of one form of a switching device, according to the teachings of the present disclosure;

FIG. 2 shows a block circuit diagram of one form of a voltage supply system, according to the teachings of the present disclosure;

FIG. 3 shows a block circuit diagram of another form of a voltage supply system, according to the teachings of the present disclosure;

FIG. 4, shows a flow diagram of one form of a method according to the teachings of the present disclosure; and

FIG. 5 shows a flow diagram of one form of a manufacturing method, according to the teachings of the present disclosure.

The drawings described herein are for illustration purposes only and are not intended to limit the scope of the teachings of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

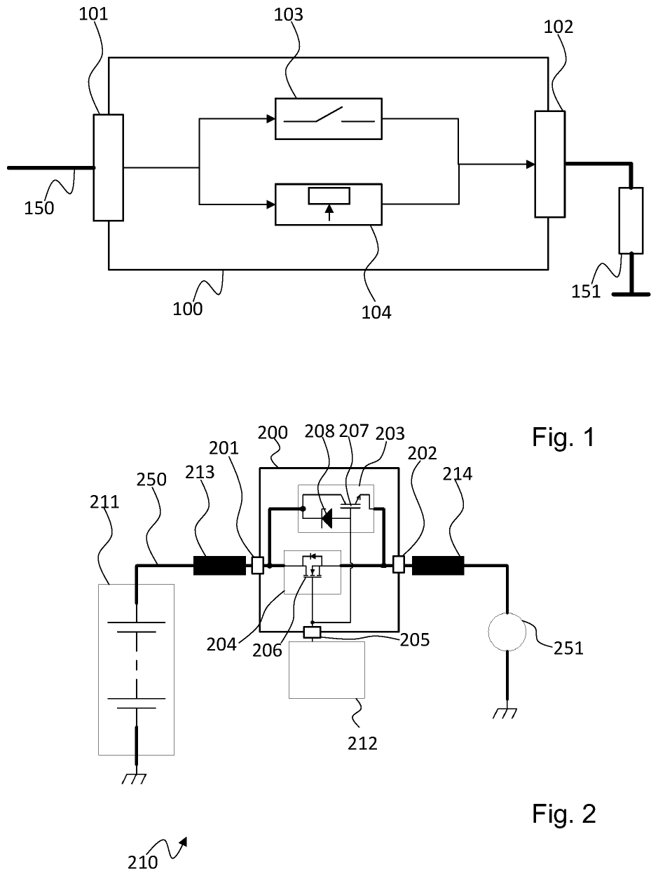

FIG. 1 shows a block circuit diagram of a switching device 100. The switching device 100 can be used, for example, in a supply line 150 for supplying electrical loads 151 with electricity. For example, the load 151 can be an electric motor in an electric vehicle.

The switching device 100 includes a power input 101 and a power output 102. The power input 101 can be coupled to an energy source, such as, for example, a vehicle battery. The power output 102 can be coupled, for example, to the input of the load, i.e., for example, of an electric motor in an electric vehicle. Here the switching device 100 can be disposed, for example, in the positive voltage branch. The vehicle mass can be used as negative voltage branch.

A controlled switching element 103 is disposed between the power input 101 and the power output 102. A regulated resistance 104 is also disposed electrically parallel to the controlled switching element 103 between the power input 101 and the power output 102.

The controlled switching element 103 can electrically couple the power input 101 to the power output 102 in a controlled manner. As already explained above, high voltage spikes can occur in particular during switching-off of inductive loads. Depending on induction and arising currents, such voltage spikes can be so high that they can damage the controlled switching element 103. In particular in the case of an emergency switching, in ongoing operation of the load 151, very high currents can be present in the system that led to corresponding voltage spikes.

In order to intercept or drain such voltage spikes, the regulated resistance 104 is provided. During opening of the controlled switching element 103, and with simultaneous occurring of voltage spikes between the power input 101 and the power output 102, the regulated resistance 104 can electrically connect the power input 101 to the power output 102.

This means that in normal operation, i.e., in the static state of the controlled switching element 103, or in a current-free switching process, the regulated resistance 104 is high-resistance, and there is no electrical connection between the power input 101 and the power output 102. It is understood that with such a “high-resistance” regulated resistance 104, the blocking resistance of the regulated resistance 104 makes possible a very low current flow between power input 101 and power output 102. However, in this context we speak of the absence of an electrical connection.

If the controlled switching element 103 is opened while a current flows through the controlled switching element 103, a voltage spike arises due to the inductances present in the system. In this operating state the contact resistance of the regulated resistance 104 is lowered, and an electrical connection arises between the power input 101 and the power output 102. The voltage spike or the energy stored in the inductances can thus be removed via the regulated resistance 104. The energy is usually converted into thermal energy.

FIG. 2 shows a block circuit diagram of a voltage supply system 210. The voltage supply system 210 includes an energy source 211, which can be configured, for example, as a battery having an output voltage of 450V. Furthermore, a load 251 is provided. A switching device 200 is provided between energy source 211 and load 251. The inductances present in the system are depicted as inductances 213, 214.

The switching device 200 is based on the switching device 100. Consequently, the switching device 200 includes a controlled switching element 203 and a regulated resistance 204, which are disposed electrically between a power input 201 and a power output 202. Furthermore, a control input 205 is provided, which is coupled to a control device 212 of the voltage supply system 210.

The controlled switching element 203 includes a MOSFET transistor 206, whose power path is disposed electrically between the power input 201 and the power output 202. The control input or gate connection of the MOSFET transistor 206 is coupled to the control input 205. The regulated resistance 204 includes an insulated-gate bipolar transistor (“IGBT”) 207, whose load path is also disposed electrically between the power input 201 and the power output 202. The control input or gate connection of the IGBT 207 is also coupled to the control input 205. Furthermore, a Zener diode 208 is disposed in the blocking direction between the load input or collector connection of the IGBT 207 and the control input or gate connection of the IGBT 207.

In this arrangement, a voltage spike, which arises via the switching device 200, ensures that the Zener diode 208 is conductive. The control input of the IGBT 207 is consequently controlled by the Zener diode 208, and the IGBT 207 is conductive or the resistance of the power path of the IGBT 207 is reduced.

If, for example, there is a sudden switching of the load current, for example, in the case of a detected short circuit in the system, then due to the energy stored in the system in the inductance a steep voltage increase or a voltage spike between power input 201 and power output 202 arises according to the formula E=1/2*L*(Iₘₐₓ)². However, the maximum dielectric strength of the power MOSFET 206 must not be exceeded.

The Zener diode 208 can consequently be chosen such that the value of the terminal voltage over the power semiconductor 207 remains below its maximum permitted limit. Due to the surge through the Zener diode 208, the IGBT 207 is set into the conductive state until the voltage drops below the Zener voltage. The IGBT 207 thereby loses its controlling and returns to the blocked state again. The energy stored in the system then leads to a renewed voltage increase between power input 201 and power output 202 until the Zener diode 208 and the IGBT 207 are conductive again. This process repeats until the stored energy is removed. As already explained above, the IGBT 207 is in a regulated state or in a linear mode here. Due to the gate source voltage, the conductivity of the IGBT 207 is regulated such that the product of the load current, which decreases linearly and its ON resistance remains nearly constant. This voltage decreasing via the IGBT corresponds to the sum of the Zener voltage of the Zener diode 208 and the gate source voltage.

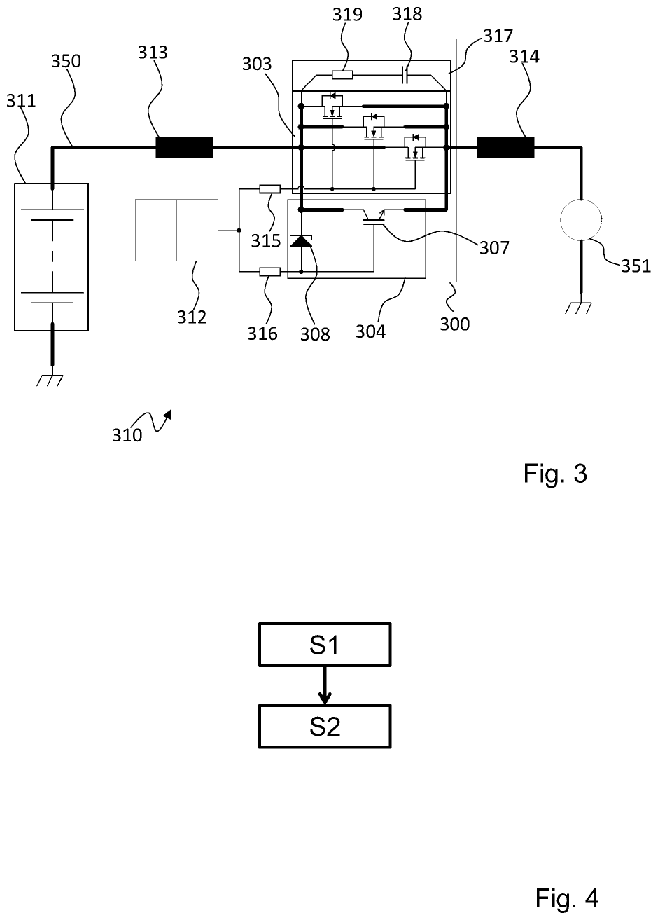

FIG. 3 shows a block circuit diagram of a voltage supply system 310. The voltage supply system 310 is based on the voltage supply system 210. Consequently, the voltage supply system 310 includes an energy source 311, which can be configured, for example, as a battery having an output voltage of 450V. Furthermore, a load 351 is provided. A switching device 300 is provided between energy source 311 and load 351. The inductances present in the system are depicted as inductances 313, 214.

The switching device 300 is based on the switching device 200. Consequently, the switching device 300 includes a controlled switching element 303 and a regulated resistance 304, which are disposed electrically between the inductance 313 and the inductance 314. The controlled switching element 303 includes a parallel circuit made of three MOSFET transistors (for the sake of clarity not drawn separately), whose power paths are disposed electrically between the inductance 313 and the inductance 314. The control inputs or gate connections of the MOSFET transistors are coupled to the control device 312 via a first series resistance.

The regulated resistance 304 includes an IGBT 307 whose load path is also disposed electrically between the inductance 313 and the inductance 314. The control input or gate connection of the IGBT 307 is also coupled to the control device 312 via a second series resistance 316. Furthermore, a Zener diode 308 is disposed in the blocking direction between the load input or collector connection of the IGBT 307 and the control input or gate connection of the IGBT 307.

In the arrangement of FIG. 3, the controlled switching element 303 and the regulated resistance 304 are consequently simultaneously controlled by the control device 312. In the static case the three MOSFETs of the controlled switching element 303 are controlled by the control device 312 via the first series resistance 315. Despite its controlling via the second series resistance 316, the IGBT 307 lying parallel to the MOSFETs remains currentless, since its collector-emitter saturation voltage VCE-Sat is significantly higher than the voltage decrease over the entire RDS-on of the three MOSFETs.

As already explained above, a controlling of the IGBT 307 only occurs with the emergence of the voltage spikes between the power input and the power output of the switching element 303, due to the switching of the load current, which voltage spikes are higher than the Zener voltage of the Zener diode 308.

During switching-off of a load, in order to eliminate the crossover distortions during the commutating phase of the current from the controlled switching element 303 to the regulated resistance 304, a damping element 317 is further provided, which includes a parallel circuit made of a capacitance 318 and a resistance 319.

To more easily understand, in the following description the reference numbers are maintained as reference with respect to FIGS. 1-3.

FIG. 4 shows a flow diagram of one form of a method for operating a switching device 100, 200, 300 for a supply line 150, 250, 350 for supplying electrical loads 151, 251, 351 with electrical energy.

In a first step S1 of the controlling, a controlled switching element 103, 203, 303 in the switching device 100, 200, 300 is controlled, which switching element 103, 203, 303 is disposed electrically between a power input 101, 201 and a power output 102, 202 of the switching device 100, 200, 300. The controlled switching element 103, 203, 303 is configured to electrically couple the power input 101, 201 to the power output 102, 202 in a controlled manner or to separate them from each other.

In a second step S2 of the connecting, the power input 101, 201 and the power output 102, 202 are connected using an electrical connection via a regulated resistance 104, 204, 304 that is disposed electrically parallel to the controlled switching element 103, 203, 303 when voltage spikes occur during opening of the controlled switching element 103, 203, 303.

It is understood that the method can be refined in a manner analogous to or corresponding to the forms of the switching device.

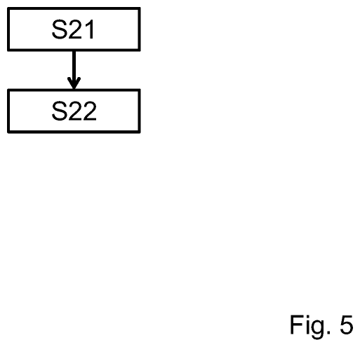

FIG. 5 shows a flow diagram of one form of a manufacturing method for a switching device 100, 200, 300 for switching in a supply line 150, 250, 350 for supplying electrical loads 151, 251, 351 with electrical energy.

In a first step S21 of the disposing, a controlled switching element 103, 203, 303 is disposed electrically between a power input 101, 201 and a power output 102, 202 of the switching device 100, 200, 300. The controlled switching element 103, 203, 303 is configured to electrically couple the power input 101, 201 to the power output 102, 202 in a controlled manner. In a second step S22 of the disposing, a regulated resistance 104, 204, 304 is disposed electrically parallel to the controlled switching element 103, 203, 303. The regulated resistance 104, 204, 304 is configured to electrically connect the power input to the power output during opening of the controlled switching element 103, 203, 303, and occurring of voltage spikes between the power input 101, 201 and the power output 102, 202.

The disposing of a controlled switching element 103, 203, 303 can include, for example, disposing a semiconductor switch, in particular a MOSFET 206, or a parallel circuit of at least two semiconductor switches, in particular MOSFETs. The disposing of a regulated resistance 104, 204, 304 can further include disposing a semiconductor switching element, wherein a power input 101, 201 of the semiconductor switching element is coupled to the power input 101, 201 of the switching device 100, 200, 300, wherein a power output 102, 202 of the semiconductor switching element is coupled to the power output 102, 202 of the switching device 100, 200, 300.

The switching device 100, 200, 300 can include a control input 205. A switching input of the controlled switching element 103, 203, 303 can be coupled to the control input 205 via a first series resistance 315. A control input of the regulated resistance 104, 204, 304 can be coupled to the control input 205 via a second series resistance 316.

An IGBT 207, 307 can be used, for example, as regulated resistance 104, 204, 304. Furthermore, a Zener diode 208, 308 can be disposed in the blocking direction between the power input 101, 201 of the switching device 100, 200, 300 and a control input of the IGBT 207, 307. The Zener diode 208, 308 can in particular be dimensioned such that its breakdown voltage falls below a maximum voltage permitted for the controlled switching element 103, 203, 303.

Finally, a damping element 317, in particular a series circuit made of a capacitance 318 and a resistance 319, can be disposed between the power input 101, 201 of the switching device 100, 200, 300 and the power output 102, 202 of the switching device 100, 200, 300.

Since the above-described devices and methods described in detail are one or more forms, they can be modified in a conventional manner by the person skilled in the art to a wide extent without leaving the field of the disclosure. In particular, the mechanical assemblies and the size ratios of the individual elements with respect to one another are only examples.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

In this application, the term “controller” and/or “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components (e.g., op amp circuit integrator as part of the heat flux data module) that provide the described functionality; or a combination of some or all of the above, such as in a system-on-chip.

The term memory is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A switching device for a supply line for supplying electrical loads with electricity, the switching device comprising:
a power input;
a power output;
a controlled switching element disposed electrically between the power input and the power output and configured to electrically couple the power input to the power output in a controlled manner; and
a regulated resistance disposed electrically parallel to the controlled switching element and configured to electrically connect the power input to the power output during opening of the controlled switching element and occurring of voltage spikes between the power input and the power output.

2. The switching device according to claim 1, wherein the controlled switching element includes a semiconductor switch.

3. The switching device according to claim 2, wherein the semiconductor switch is a MOSFET.

4. The switching device according to claim 1, wherein the controlled switching element includes a parallel circuit of at least two semiconductor switches.

5. The switching device according to claim 4, wherein the semiconductor switches are MOSFETs.

6. The switching device according to claim 1, wherein the regulated resistance includes a semiconductor switching element, wherein a power input of the semiconductor switching element is coupled to the power input of the switching device, and wherein a power output of the semiconductor switching element is coupled to the power output of the switching device.

7. The switching device according to claim 1, further comprising:
a control input,
wherein a switching input of the controlled switching element is coupled to the control input via a first series resistance, and/or a control input of the regulated resistance is coupled to the control input via a second series resistance.

8. The switching device according to claim 1, wherein the regulated resistance is configured as an insulated-gate bipolar transistor (“IGBT”), and wherein a Zener diode is disposed in a blocking direction between the power input of the switching device and a control input of the IGBT.

9. The switching device according to claim 8, wherein the Zener diode is dimensioned such that its breakdown voltage lies below a maximum voltage permitted for the controlled switching element.

10. The switching device according to claim 1, further comprising:
a damping element, the damping element comprising a series circuit made of a capacitance and a resistance, is the damping element being disposed between the power input of the switching device and the power output of the switching device.

11. A voltage supply system for supplying electrical loads with electricity, the voltage supply system including:
an electrical energy source; and
the switching device according to claim 1,
wherein the power input of the switching device is coupled to a positive power output of the energy source, and wherein the power output of the switching device is couplable with a positive load terminal of the electrical loads.

12. A method for operating a switching device for a supply line for supplying electrical loads with electricity, the method comprising:
controlling a controlled switching element in the switching device, the switching element being disposed electrically between a power input and a power output of the switching device and configured to electrically couple the power input to the power output in a controlled manner or to separate the power input and the power output from each other, and
connecting the power input and the power output using an electrical connection via a regulated resistance disposed electrically parallel to the controlled switching element, during opening of the controlled switching element and occurring of voltage spikes.

13. A manufacturing method for a switching device for switching in a supply line for supplying electrical loads with electricity, the manufacturing method comprising:
disposing a controlled switching element electrically between a power input and a power output of the switching device in a controlled manner, the switching element being configured to electrically couple the power input to the power output in a controlled manner; and
disposing a regulated resistance electrically parallel to the controlled switching element, the regulated resistance being configured to electrically connect the power input to the power output during opening of the controlled switching element and occurring of voltage spikes between the power input and the power output.

14. The manufacturing method according to claim 13, wherein the disposing of a controlled switching element includes disposing a semiconductor switch, and/or the disposing of a regulated resistance includes disposing a semiconductor switching element, wherein a power input of the semiconductor switching element is coupled to the power input of the switching device, and wherein a power output of the semiconductor switching element is coupled to the power output of the switching device.

15. The manufacturing method according to claim 13, wherein the switching device includes a control input, wherein a switching input of the controlled switching element is coupled to the control input via a first series resistance, and/or wherein a control input of the regulated resistance is coupled to the control input via a second series resistance.

16. The manufacturing method according to claim 13, wherein an insulated-gate bipolar transistor (“IGBT”) is disposed as the regulated resistance, and wherein a Zener diode is disposed in a blocking direction between the power input of the switching device and a control input of the IGBT.

17. The manufacturing method according to claim 16, wherein the Zener diode is dimensioned such that its breakdown voltage is below a maximum voltage permitted for the controlled switching element.

18. The manufacturing method according to claim 13, wherein a damping element comprising a series circuit made of a capacitance and a resistance, is disposed between the power input of the switching device and the power output of the switching device.
